(19) United States
(12) Patent Application Publication
(10) Pub. No.: US 2026/0140206 A1
(43) Pub. Date: May 21, 2026

(54) METHOD FOR PRODUCING ALKALI VAPOR CELL AND ALKALI VAPOR CELL

(71) Applicant: Hamamatsu Photonics K.K., Hamamatsu-shi (JP)

(72) Inventors: Masaki YAMADA, Hamamatsu-shi (JP); Naoki Umebayashi, Hamamatsu-shi (JP); Yuji Ogida, Hamamatsu-shi (JP)

(73) Assignee: Hamamatsu Photonics K.K., Hamamatsu-shi (JP)

(21) Appl. No.: 18/954,829

(22) Filed: Nov. 21, 2024

(51) Int. Cl. G01R 33/032; G01R 33/26

(52) U.S. Cl. CPC G01R 33/032; G01R 33/26

(57) ABSTRACT

A method for producing an alkali vapor cell includes a step of preparing a first member and a second member constituting at least a part of a container for enclosing an alkali metal; a step of forming a first antireflection film on a first surface of the first member; a step of forming a second antireflection film on a second surface of the first member, the second surface being opposite to the first surface; and a step of bonding the first member and the second member to each other by anodic bonding.

### TECHNICAL FIELD

One aspect of the present disclosure relates to a method for producing an alkali vapor cell and an alkali vapor cell.

### BACKGROUND

An atomic oscillator is known which includes an alkali vapor cell in which an alkali metal is enclosed, a light source for illuminating a laser beam to the alkali vapor cell, and a photodetector for detecting light that has passed through the alkali vapor cell (for example, Japanese Unexamined Patent Publication No. 2018-132348).

### SUMMARY

A container of an alkali vapor cell used in an atomic oscillator is sometimes formed by bonding a plurality of members by heat sealing. In this case, there is a possibility that the container is distorted or an antireflection film formed on the surface of the container is destroyed due to heat involved in the heat sealing, and the accuracy of measurement using an alkali vapor cell is reduced. Methods for bonding a plurality of members constituting a container of an alkali vapor cell include a method using an adhesive or frit glass. However, in the method using an adhesive or frit glass, there is a possibility that the accuracy of measurement using an alkali vapor cell is reduced due to the release of gas from the adhesive or the like.

An object of one aspect of the present disclosure is to provide a method for producing an alkali vapor cell with which accurate measurement can be made, and the alkali vapor cell.

### Solution to Problem

A method for producing an alkali vapor cell according to an aspect of the present disclosure is [1] “a method for producing an alkali vapor cell including a step of preparing a first member and a second member constituting at least a part of a container for enclosing an alkali metal; a step of forming a first antireflection film on a first surface of the first member; a step of forming a second antireflection film on a second surface of the first member, the second surface being opposite to the first surface; and a step of bonding the first member and the second member to each other by anodic bonding”.

In the method for producing an alkali vapor cell according to [1] described above, the first antireflection film is formed on the first surface of the first member constituting at least a part of the container for enclosing the alkali metal, and the second antireflection film is formed on the second surface of the first member opposite to the first surface. This reduces reflection of light that has transmitted through the alkali vapor cell on the first surface and the second surface, so that measurement using the alkali vapor cell can be accurately made. In the method for producing an alkali vapor cell, the first member and the second member are bonded to each other by anodic bonding. This reduces distortion of the first member and the second member due to heat and reduces destruction of the first antireflection film and the second antireflection film, for example, as compared with a case where the first member and the second member are bonded to each other by heat sealing, so that measurement using the alkali vapor cell can be accurately made. Further, in a case where the first member and the second member are bonded to each other using an adhesive or frit glass, there is a possibility that gas is released from the adhesive or the like. However, in the case of anodic bonding, such release of gas is reduced, so that measurement using the alkali vapor cell can be accurately made. Thus, according to the method for producing an alkali vapor cell, it is possible to produce an alkali vapor cell with which measurement can be accurately made.

A method for producing an alkali vapor cell according to an aspect of the present disclosure may be [2] “the method for producing an alkali vapor cell according to [1] described above, further including a step of forming a bonding member for bonding the first member and the second member with silicon, in which in the step of forming the bonding member, the bonding member is formed so as to surround the first antireflection film on the first surface, and in the step of bonding, the first member and the second member are bonded to each other via the bonding member”. In this case, by configuring a silicon member for anodic bonding (bonding member) different from the second member, the flexibility to select materials for the second member is improved. For example, the second member can be formed of glass that is relatively easily processed, and the first member and the second member can be bonded to each other by anodic bonding via a bonding member (silicon member).

A method for producing an alkali vapor cell according to an aspect of the present disclosure may be [3] “the method for producing an alkali vapor cell according to [1] described above, in which the second member is formed of silicon, and in the step of bonding, the first member and the second member are directly bonded to each other”. In this case, the first member and the second member can be bonded to each other by anodic bonding without preparing the silicon member for anodic bonding as a configuration different from the second member. The second member is formed of silicon having relatively high resistance to an alkali metal, which can reduce a chemical reaction between the alkali metal and the second member (for example, corrosion of the second member).

A method for producing an alkali vapor cell according to an aspect of the present disclosure may be [4] “the method for producing an alkali vapor cell according to any one of [1] to [3] described above, in which the second member includes a wall portion extending so as to surround a space and a tube portion formed on the wall portion, and one end of the tube portion communicates with the space”. In this case, an alkali metal can be easily introduced into the alkali vapor cell through a tube portion.

A method for producing an alkali vapor cell according to an aspect of the present disclosure may be [5] “the method for producing an alkali vapor cell according to any one of [1] to [4] described above, in which in the step of forming the first antireflection film, the first antireflection film is formed by vapor deposition or sputtering”. In this case, the first antireflection film can be formed by a simpler method.

A method for producing an alkali vapor cell according to an aspect of the present disclosure may be [6] “the method for producing an alkali vapor cell according to any one of [1] to [5] described above, in which in the step of forming the second antireflection film, the second antireflection film is formed by vapor deposition or sputtering”. In this case, the second antireflection film can be formed by a simpler method.

A method for producing an alkali vapor cell according to an aspect of the present disclosure may be [7] “the method for producing an alkali vapor cell according to any one of [1] to [5] described above, in which in the step of forming the first antireflection film, the first antireflection film is formed of aluminum oxide, silicon dioxide, magnesium fluoride, hafnium oxide, tantalum pentoxide, or titanium dioxide”. In this case, reflection of light on the first surface can be reduced more reliably by the first antireflection film.

A method for producing an alkali vapor cell according to an aspect of the present disclosure may be [8] “the method for producing an alkali vapor cell according to any one of [1] to [7] described above, in which in the step of forming the second antireflection film, the second antireflection film is formed of aluminum oxide, silicon dioxide, magnesium fluoride, hafnium oxide, tantalum pentoxide, or titanium dioxide”. In this case, reflection of light on the second surface can be more reliably reduced by the second antireflection film.

A method for producing an alkali vapor cell according to an aspect of the present disclosure may be [9] “the method for producing an alkali vapor cell according to any one of [1] to [8] described above, further including a step of forming, on the first member, a first protective film containing aluminum oxide or magnesium fluoride, and a step of forming, on the second member, a second protective film containing aluminum oxide or magnesium fluoride, in which the second member includes a third surface defining an internal space of the container, the step of forming the first protective film is a step of forming the first protective film on the first surface before the step of forming the first antireflection film, and in the step of forming the second protective film, the second protective film is formed on the third surface”. In this case, the protective film containing aluminum oxide or magnesium fluoride having relatively high resistance to an alkali metal is formed on the first surface and the third surface. This can reduce a chemical reaction between the alkali metal and the first surface (for example, corrosion of the first surface) and a chemical reaction between the alkali metal and the third surface (for example, corrosion of the third surface).

An alkali vapor cell according to an aspect of the present disclosure is [10] “an alkali vapor cell including a first member and a second member constituting at least a part of a container for enclosing an alkali metal; and a first antireflection film and a second antireflection film formed on the first member, in which the first member includes a first surface and a second surface, the first surface being an inner surface of the container, the second surface being located on a side opposite to the first surface and being an outer surface of the container, the first antireflection film is formed on the first surface, the second antireflection film is formed on the second surface, and the first member and the second member are bonded to each other by anodic bonding”.

In the alkali vapor cell according to [10] described above, the first antireflection film is formed on the first surface of the first member constituting at least a part of the container for enclosing the alkali metal, and the second antireflection film is formed on the second surface of the first member opposite to the first surface. This reduces reflection of light that has transmitted through the alkali vapor cell on the first surface and the second surface, so that measurement using the alkali vapor cell can be accurately made. In the alkali vapor cell, the first member and the second member are bonded to each other by anodic bonding. This reduces, in the production process of the alkali vapor cell, distortion of the first member and the second member due to heat and reduces destruction of the first antireflection film and the second antireflection film, for example, as compared with a case where the first member and the second member are bonded to each other by heat sealing, so that measurement using the alkali vapor cell can be accurately made. Further, in a case where the first member and the second member are bonded to each other using an adhesive or frit glass, there is a possibility that gas is released from the adhesive or the like. However, in the case of anodic bonding, such release of gas is reduced, so that measurement using the alkali vapor cell can be accurately made. Therefore, according to the alkali vapor cell, measurement can be accurately made.

An alkali vapor cell according to an aspect of the present disclosure may be [11] “the alkali vapor cell according to [10] described above, further including a bonding member formed on the first surface so as to surround the first antireflection film, in which the bonding member is formed of silicon, and the first member and the second member are bonded to each other via the bonding member”. In this case, by configuring a silicon member for anodic bonding (bonding member) different from the second member, the flexibility to select materials for the second member is improved. For example, the second member can be formed of glass that is relatively easily processed, and the first member and the second member can be bonded to each other by anodic bonding via a bonding member (silicon member).

An alkali vapor cell according to an aspect of the present disclosure may be [12] “the alkali vapor cell according to [10] described above, in which the second member is formed of silicon, and the first member and the second member are directly bonded to each other”. In this case, the first member and the second member can be bonded to each other by anodic bonding without preparing the silicon member for anodic bonding as a configuration different from the second member. The second member is formed of silicon having relatively high resistance to an alkali metal, which can reduce a chemical reaction between the alkali metal and the second member (for example, corrosion of the second member).

An alkali vapor cell according to an aspect of the present disclosure may be [13] “the alkali vapor cell according to any one of [10] to [12] described above, in which the second member includes a wall portion extending so as to surround a space and a tube portion formed on the wall portion, and one end of the tube portion communicates with the space”. In this case, an alkali metal can be easily introduced into the alkali vapor cell through a tube portion.

An alkali vapor cell according to an aspect of the present disclosure may be [14] “the alkali vapor cell according to any one of [10] to [13] described above, in which the first antireflection film is formed of aluminum oxide, silicon dioxide, magnesium fluoride, hafnium oxide, tantalum pentoxide, or titanium dioxide”. In this case, reflection of light on the first surface can be reduced more reliably by the first antireflection film.

An alkali vapor cell according to an aspect of the present disclosure may be [15] “The alkali vapor cell according to any one of [10] to [14] described above, in which the second antireflection film is formed of aluminum oxide, silicon dioxide, magnesium fluoride, hafnium oxide, tantalum pentoxide, or titanium dioxide”. In this case, reflection of light on the second surface can be more reliably reduced by the second antireflection film.

An alkali vapor cell according to an aspect of the present disclosure may be [16] “the alkali vapor cell according to any one of [10] to [15] described above, further including a first protective film formed on the first member and containing aluminum oxide or magnesium fluoride, and a second protective film formed on the second member and containing aluminum oxide or magnesium fluoride, in which the second member includes a third surface defining an internal space of the container, the first protective film is formed on the first surface, and the second protective film is formed on the third surface”. In this case, the protective film containing aluminum oxide or magnesium fluoride having relatively high resistance to an alkali metal is formed on the first surface and the third surface. This can reduce a chemical reaction between the alkali metal and the first surface (for example, corrosion of the first surface) and a chemical reaction between the alkali metal and the third surface (for example, corrosion of the third surface).

According to one aspect of the present disclosure, it is possible to provide a method for producing an alkali vapor cell with which accurate measurement can be made, and the alkali vapor cell.

### BRIEF DESCRIPTION OF THE DRAWINGS

FIG. 1 is a diagram schematically illustrating an atomic oscillator having an alkali vapor cell according to a first embodiment;

FIG. 2 is a perspective view of the alkali vapor cell according to the first embodiment;

FIG. 3 is a perspective view of a second member of the alkali vapor cell illustrated in FIG. 1;

FIG. 4 is a plan view of a first member and a bonding member of the alkali vapor cell illustrated in FIG. 1;

FIG. 5 is a cross-sectional view of the alkali vapor cell taken along line V-V illustrated in FIG. 2;

FIG. 6 is a cross-sectional view of an antireflection coating illustrated in FIG. 1;

FIG. 7 is a cross-sectional view of the antireflection coating illustrated in FIG. 1;

FIG. 8 is a perspective view of the alkali vapor cell according to the first embodiment;

FIG. 9 is a cross-sectional view of the alkali vapor cell taken along line IX-IX illustrated in FIG. 8;

FIG. 10 is a perspective view of an alkali vapor cell according to a modification;

FIG. 11 is a cross-sectional view of the alkali vapor cell taken along line XI-XI illustrated in FIG. 10;

FIG. 12 is a perspective view of an alkali vapor cell according to a modification;

FIG. 13 is a perspective view of a second member of the alkali vapor cell illustrated in FIG. 12;

FIG. 14 is a perspective view of an alkali vapor cell according to a modification;

FIG. 15 is a perspective view of an alkali vapor cell according to a modification;

FIG. 16 is a perspective view of a second member of the alkali vapor cell illustrated in FIG. 15; and

FIG. 17 is a perspective view of an alkali vapor cell according to a modification.

### DETAILED DESCRIPTION

Hereinafter, embodiments of the present disclosure will be described in detail with reference to the drawings. In the drawings, the same or corresponding parts are denoted by the same reference signs, and redundant description will be omitted.

### First Embodiment

### Configuration and Operation of Atomic Oscillator

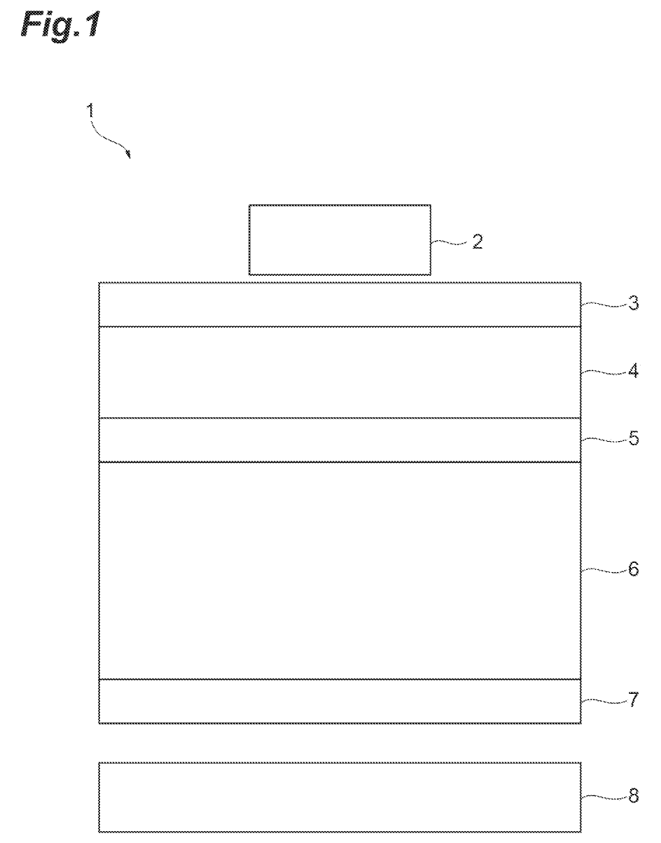

As illustrated in FIG. 1, an atomic oscillator 1 includes a light source 2, a heater 3, a spacer 4, an optical element 5, an alkali vapor cell 6, a heater 7, and a photodetector 8. The atomic oscillator 1 is used for a quantum sensor such as an atomic clock, a quantum memory, a gyro sensor, or a magnetic sensor.

The light source 2 irradiates the alkali vapor cell 6 with light. The light source 2 may be, for example, a light emitting element such as a vertical cavity surface emitting laser (VCSEL). The light from the light source 2 pumps atoms of an alkali metal enclosed in the alkali vapor cell 6. The heater 3 is disposed between the light source 2 and the spacer 4. The heater 3 is used to adjust the temperature of the light source 2. The spacer 4 is disposed between the light source 2 and the optical element 5. The optical element 5 is disposed between the spacer 4 and the alkali vapor cell 6. The optical element 5 is a wave plate for changing the polarization direction of light from the light source 2 to a specific direction.

The alkali vapor cell 6 is a container in which the alkali metal and a buffer gas are enclosed. A detailed configuration of the alkali vapor cell 6 will be described later. The heater 7 is disposed between the alkali vapor cell 6 and the photodetector 8. The heater 7 is used to adjust the temperature of the alkali vapor cell 6. The photodetector 8 detects light that has transmitted through the alkali vapor cell 6. The photodetector 8 is configured to include an element that converts light into an electric signal, such as a photodiode.

The alkali vapor cell 6 is heated by the heater 7, and thereby an alkali metal gas is generated inside the alkali vapor cell 6. In this state, the light emitted from the light source 2 passes through the optical element 5 to enter the alkali vapor cell 6. The alkali metal atoms enclosed in the alkali vapor cell 6 are pumped by the light irradiation. The light that has transmitted through the alkali vapor cell 6 is detected by the photodetector 8 and converted into an electric signal. The signal acquired by the photodetector 8 is used as feedback information, for example, for controlling the light source 2.

### Configuration of Alkali Vapor Cell

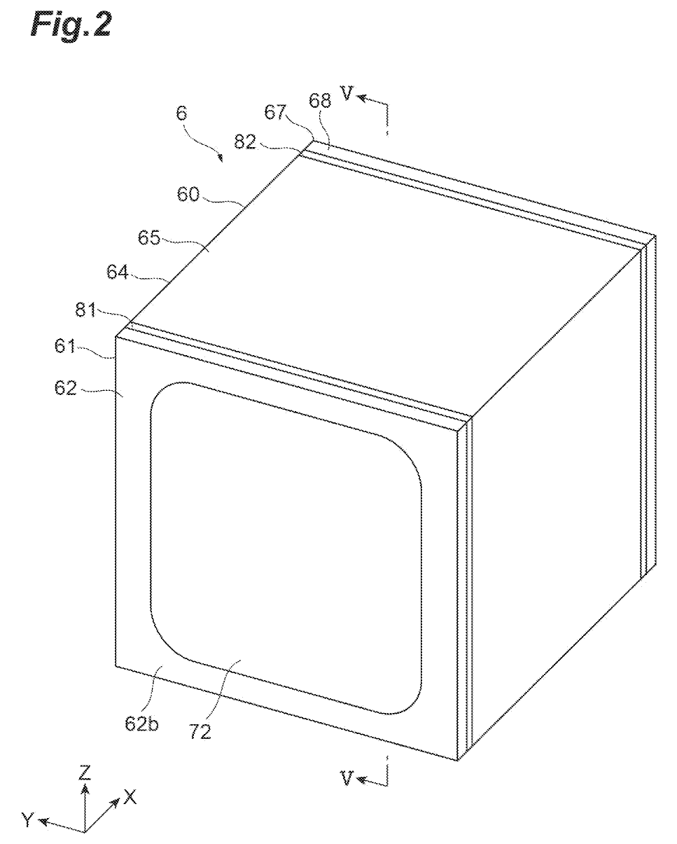

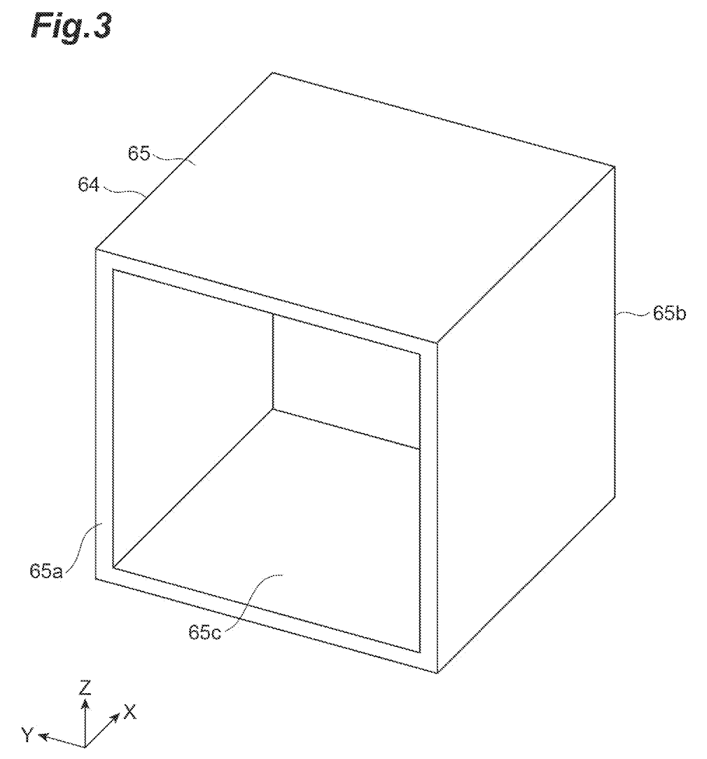

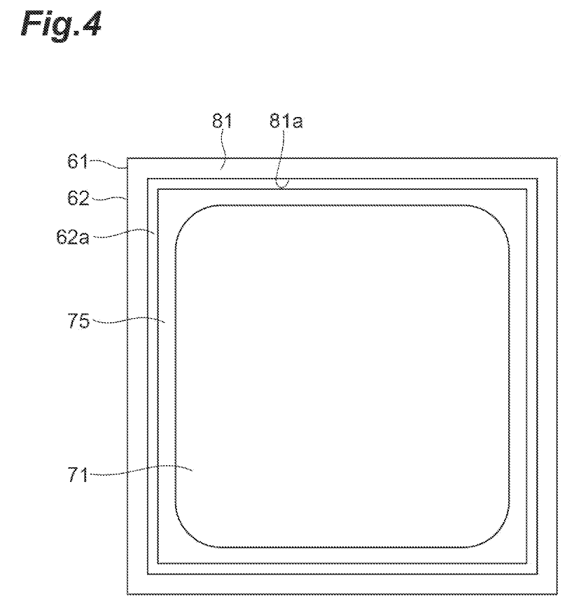

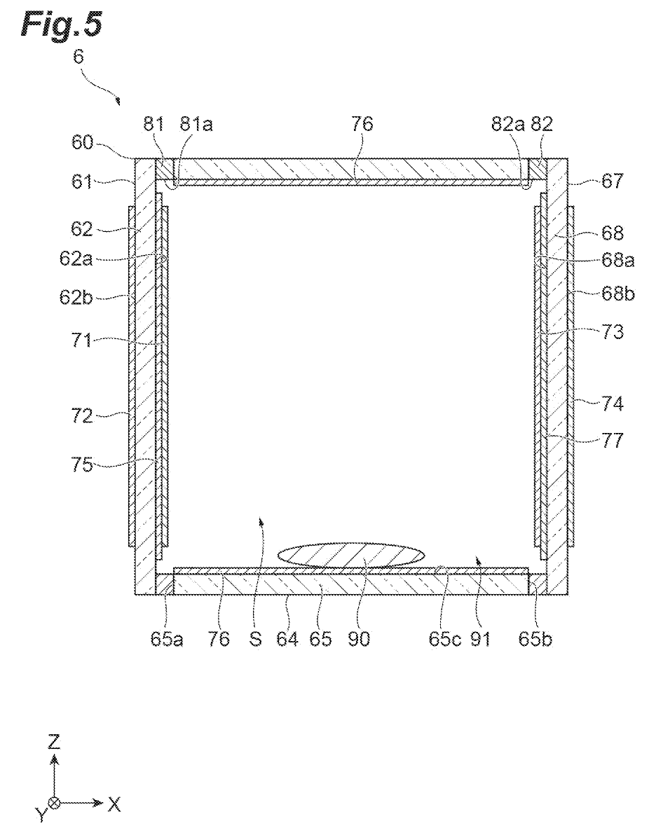

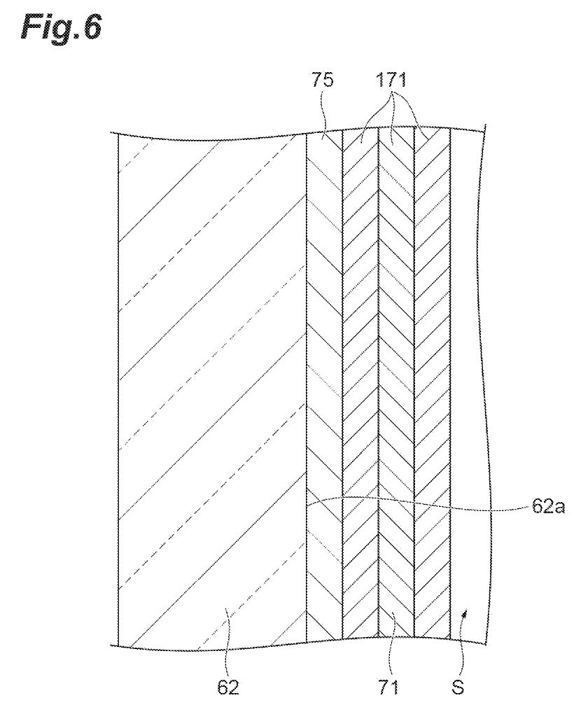

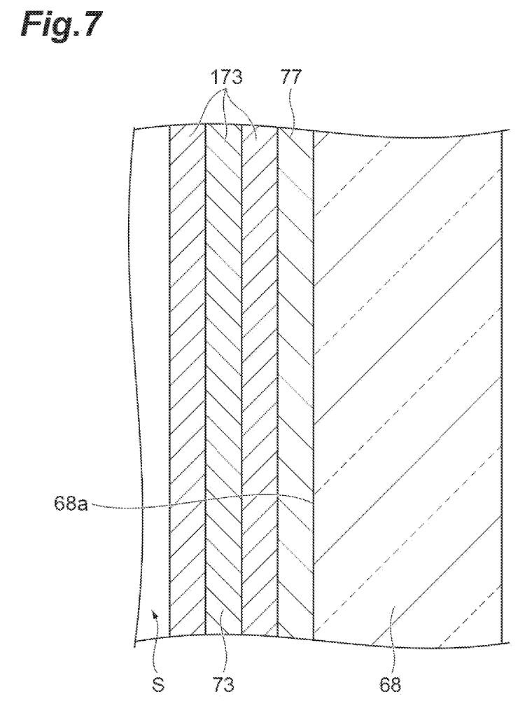

A detailed configuration of the alkali vapor cell 6 will be described with reference to FIGS. 2 to 7. FIG. 2 is a perspective view of the alkali vapor cell 6. FIG. 3 is a perspective view of a second member 64 of the alkali vapor cell 6 illustrated in FIG. 1. FIG. 4 is a plan view of a first member 61 and a bonding member 81 of the alkali vapor cell 6 illustrated in FIG. 1. FIG. 5 is a cross-sectional view of the alkali vapor cell 6 taken along line V-V illustrated in FIG. 2. FIG. 6 is a cross-sectional view of an antireflection coating 71 illustrated in FIG. 1. FIG. 7 is a cross-sectional view of an antireflection coating 72 illustrated in FIG. 1. Hereinafter, a direction of light incidence with respect to the alkali vapor cell 6 is referred to as an X-axis direction, one direction perpendicular to the X-axis direction is referred to as a Y-axis direction, and a direction perpendicular to both the X-axis direction and the Y-axis direction is referred to as a Z-axis direction.

The alkali vapor cell 6 includes the first member 61, the second member 64, a third member 67, the antireflection coating 71, the antireflection coating 72, an antireflection coating 73, an antireflection coating 74, a protective coating 75, a protective coating 76, a protective coating 77, a bonding member 81, a bonding member 82, an alkali metal 90, and a buffer gas 91. An antireflection coating is an example of an antireflection film. A protective coating is an example of a protective film. In this example, the first member 61, the second member 64, the third member 67, the bonding member 81, and the bonding member 82 constitute a container 60 that encloses the alkali metal 90 and the buffer gas 91. In other words, the container 60 includes the first member 61, the second member 64, the third member 67, the bonding member 81, and the bonding member 82.

The first member 61 includes a substrate portion 62. The substrate portion 62 is formed of glass. The substrate portion 62 has optical transparency. The optical transparency is the property of a material to allow light from the light source 2 to pass through the material. Specifically, the optical transparency means that the light transmittance with respect to the light from the light source 2 is 30% or more. The substrate portion 62 is formed in a rectangular plate shape having a thickness along the X-axis direction. The width of the substrate portion 62 along the Y-axis direction and the width of the substrate portion 62 along the Z-axis direction are, for example, about several millimeters.

The substrate portion 62 has a main surface (first surface) 62a and a main surface (second surface) 62b. The main surface 62a and the main surface 62b are surfaces perpendicular to the X-axis direction. The main surface 62a and the main surface 62b each have a rectangular shape when viewed from the X-axis direction. The main surface 62a is an inner surface of the alkali vapor cell 6 (constitutes a part of the inner surface). The main surface 62b is an outer surface of the alkali vapor cell 6 (constitutes a part of the outer surface). The main surface 62b is located on the side opposite to the main surface 62a.

The second member 64 has a wall portion 65. In this example, the second member 64 is configured with the wall portion 65. The wall portion 65 is formed of glass. The wall portion 65 has optical transparency. The wall portion 65 is formed in a frame shape along the outer edge of the main surface 62a. The wall portion 65 surrounds the space on the main surface 62a. The space on the main surface 62a surrounded by the wall portion 65 corresponds to an internal space S of the alkali vapor cell 6 (container 60). When viewed from the X-axis direction, each of the inner edge and the outer edge of the wall portion 65 has a rectangular shape. When viewed from the X-axis direction, the center of the inner edge of the wall portion 65 is aligned with the center of each of the antireflection coatings 71, 72, 73, and 74 to be described later.

The wall portion 65 has a pair of end faces 65a and 65b. The end face 65a is located on the side opposite to the end face 65b in the X-axis direction (closer to the first member 61 than the end face 65b is). Each of the end face 65a and the end face 65b is formed in a rectangular frame shape. The wall portion 65 further includes an inner surface 65c (third surface). The inner surface 65c is a surface that defines the inner edge of the wall portion 65 when viewed from the X-axis direction. The inner surface 65c defines the internal space S together with the main surface 62a and a main surface 68a of a substrate portion 68 of the third member 67 described later. No antireflection coating is formed on the inner surface 65c.

The third member 67 includes the substrate portion 68. The substrate portion 68 is formed of glass. The substrate portion 68 has optical transparency. The substrate portion 68 is formed in a rectangular plate shape having a thickness along the X-axis direction. The width of the substrate portion 68 along the Y-axis direction and the width of the substrate portion 68 along the Z-axis direction are, for example, about several millimeters.

The substrate portion 68 has the main surface 68a and a main surface 68b. The main surface 68a and the main surface 68b are surfaces perpendicular to the X-axis direction. The main surface 68a and the main surface 68b each have a rectangular shape when viewed from the X-axis direction. The main surface 68a is an inner surface of the alkali vapor cell 6 (constitutes a part of the inner surface). The main surface 68b is an outer surface of the alkali vapor cell 6 (constitutes a part of the outer surface). The main surface 68b is located on the side opposite to the main surface 68a.

The antireflection coating (first antireflection film) 71 is formed on the main surface 62a. In this example, the antireflection coating 71 is formed on the main surface 62a via the protective coating 75 described later. The antireflection coating 71 is directly formed on the protective coating 75. The antireflection coating 71 is formed in a rectangular shape with rounded corners when viewed from the X-axis direction. The antireflection coating 71 is an AR coat that suppresses reflection of light from the light source 2 on the main surface 62a.

In this example, the antireflection coating 71 is a multilayer coating. The antireflection coating 71 is formed of a plurality of layers 171 stacked on the main surface 62a. The antireflection coating 71 (layer 171) is formed of, for example, aluminum oxide, silicon dioxide, magnesium fluoride, hafnium oxide, tantalum pentoxide, or titanium dioxide. The antireflection coating 71 is formed by, for example, vapor deposition or sputtering. The antireflection coating 71 is not formed on a bonding region (contact region) of the main surface 62a with the bonding member 81 described later.

The antireflection coating (second antireflection film) 72 is formed on the main surface 62b. The antireflection coating 72 is formed in a rectangular shape with rounded corners when viewed from the X-axis direction. The antireflection coating 72 is an AR coat that suppresses reflection of light from the light source 2 on the main surface 62b. In this example, the antireflection coating 72 is a multilayer coating formed on the main surface 62b. In this example, the antireflection coating 72 is directly formed on the main surface 62b. The antireflection coating 72 is formed of, for example, aluminum oxide, silicon dioxide, magnesium fluoride, hafnium oxide, tantalum pentoxide, or titanium dioxide. The antireflection coating 71 and the antireflection coating 72 may be formed of the same material or different materials. The antireflection coating 72 is formed by, for example, vapor deposition or sputtering. The antireflection coating 72 may be a multilayer coating similarly to the antireflection coating 71.

The antireflection coating 73 is formed on the main surface 68a. In this example, the antireflection coating 73 is formed on the main surface 68a via the protective coating 77 described later. The antireflection coating 73 is directly formed on the protective coating 77. The antireflection coating 73 is formed in a rectangular shape with rounded corners when viewed from the X-axis direction. The antireflection coating 73 is an AR coat that suppresses reflection of light from the light source 2 on the main surface 68a.

In this example, the antireflection coating 73 is a multilayer coating. The antireflection coating 73 is formed of a plurality of layers 173 stacked on the main surface 68a. The antireflection coating 73 (layer 173) is formed of, for example, aluminum oxide, silicon dioxide, magnesium fluoride, hafnium oxide, tantalum pentoxide, or titanium dioxide. The antireflection coating 73 is formed by, for example, vapor deposition or sputtering. The antireflection coating 73 is not formed on a bonding region (contact region) of the main surface 68a with the bonding member 82 described later.

The antireflection coating 74 is formed on the main surface 68b. The antireflection coating 74 is formed in a rectangular shape with rounded corners when viewed from the X-axis direction. The antireflection coating 74 is an AR coat that suppresses reflection of light from the light source 2 on the main surface 68b. In this example, the antireflection coating 74 is a multilayer coating formed on the main surface 68b. In this example, the antireflection coating 74 is directly formed on the main surface 68b. The antireflection coating 74 is formed of, for example, aluminum oxide, silicon dioxide, magnesium fluoride, hafnium oxide, tantalum pentoxide, or titanium dioxide. The antireflection coating 73 and the antireflection coating 74 may be formed of the same material or different materials. The antireflection coating 74 is formed by, for example, vapor deposition or sputtering. The antireflection coating 74 may be a multilayer coating similarly to the antireflection coating 73.

The protective coating (first protective film) 75 is a coating formed on the first member 61. In this example, the protective coating 75 is directly formed on the main surface 62a. The protective coating 75 is formed between the main surface 62a and the antireflection coating 71. The protective coating 75 is formed in a rectangular shape when viewed from the X-axis direction. When viewed from the X-axis direction, the outer edge of the protective coating 75 is located outside the outer edge of the antireflection coating 71. In other words, the protective coating 75 is larger than the antireflection coating 71. The protective coating 75 is not formed on a bonding region (contact region) of the main surface 62a with the bonding member 81 described later. The protective coating 75 is formed of, for example, a material having low reactivity with respect to the alkali metal 90, and suppresses a chemical reaction between the alkali metal 90 and the main surface 62a (for example, corrosion of the main surface 62a). In this example, the protective coating 75 contains aluminum oxide or magnesium fluoride. The protective coating 75 is formed by, for example, vapor deposition or sputtering.

The protective coating (second protective film) 76 is a coating formed on the second member 64. In this example, the protective coating 76 is directly formed on the inner surface 65c. The protective coating 76 is formed of, for example, a material having low reactivity with respect to the alkali metal 90, and suppresses a chemical reaction between the alkali metal 90 and the inner surface 65c (for example, corrosion of the inner surface 65c). In this example, the protective coating 76 contains aluminum oxide or magnesium fluoride. The protective coating 76 is formed by, for example, vapor deposition or sputtering.

The protective coating (third protective film) 77 is a coating formed on the third member 67. In this example, the protective coating 77 is directly formed on the main surface 68a. The protective coating 77 is formed between the main surface 68a and the antireflection coating 73. The protective coating 77 is formed in a rectangular shape when viewed from the X-axis direction. When viewed from the X-axis direction, the outer edge of the protective coating 77 is located outside the outer edge of the antireflection coating 73. In other words, the protective coating 77 is larger than the antireflection coating 73. The protective coating 77 is not formed on a bonding region (contact region) of the main surface 68a with the bonding member 82 described later. The protective coating 77 is formed of, for example, a material having low reactivity with respect to the alkali metal 90, and suppresses a chemical reaction between the alkali metal 90 and the main surface 68a (for example, corrosion of the main surface 68a). In this example, the protective coating 77 contains aluminum oxide or magnesium fluoride. The protective coating 77 is formed by, for example, vapor deposition or sputtering.

The bonding member 81 is disposed between the first member 61 and the second member 64 to bond the first member 61 and the second member 64 to each other. The bonding member 81 is continuously formed in a rectangular frame shape when viewed from the X-axis direction. The bonding member 81 is formed on the main surface 62a so as to surround the antireflection coating 71. The bonding member 81 is in direct contact with the main surface 62a and the end face 65a of the second member 64. The bonding member 81 is formed of silicon.

The bonding member 81 has an inner surface 81a. The inner surface 81a is a surface that defines the inner edge of the bonding member 81 when viewed from the X-axis direction. When viewed from the X-axis direction, the inner surface 81a is located outside the outer edge of the antireflection coating 71. The inner surface 81a of the bonding member 81 is not in contact with the antireflection coating 71. When viewed from the X-axis direction, the inner edge (inner surface 81a) of the bonding member 81 is aligned with the inner edge of the wall portion 65, and the outer edge of the bonding member 81 is aligned with the outer edge of the wall portion 65. No antireflection coating is formed on the inner surface 81a.

The bonding member 82 is disposed between the third member 67 and the second member 64 to bond the third member 67 and the second member 64 to each other. The bonding member 82 is continuously formed in a rectangular frame shape when viewed from the X-axis direction. The bonding member 82 is formed on the main surface 68a so as to surround the antireflection coating 73. The bonding member 82 is in direct contact with the main surface 68a and the end face 65b of the second member 64. The bonding member 82 is formed of silicon.

The bonding member 82 has an inner surface 82a. The inner surface 82a is a surface that defines the inner edge of the bonding member 82 when viewed from the X-axis direction. When viewed from the X-axis direction, the inner surface 82a is located outside the outer edge of the antireflection coating 73. The inner surface 82a of the bonding member 82 is not in contact with the antireflection coating 73. When viewed from the X-axis direction, the inner edge (inner surface 82a) of the bonding member 82 is aligned with the inner edge of the wall portion 65, and the outer edge of the bonding member 82 is aligned with the outer edge of the wall portion 65. No antireflection coating is formed on the inner surface 82a.

The alkali metal 90 is enclosed in the internal space S. The alkali metal 90 is disposed in the container 60. In this example, the alkali metal 90 is disposed on the inner surface 65c of the wall portion 65. The alkali metal 90 may be a simple substance of an alkali metal or a compound (for example, an azide). The alkali metal 90 may include, for example, cesium, rubidium, potassium, sodium, or lithium. The buffer gas 91 is enclosed in the internal space S. The buffer gas 91 is, for example, an inert gas such as nitrogen, argon, helium, or neon.

The first member 61 and the second member 64 are bonded to each other by anodic bonding. The first member 61 and the second member 64 are bonded to each other via the bonding member 81. The third member 67 and the second member 64 are bonded to each other by anodic bonding. The third member 67 and the second member 64 are bonded to each other via the bonding member 82. Since the first member 61 and the second member 64 are bonded to each other, and further, the third member 67 and the second member 64 are bonded to each other, the internal space S is hermetically sealed.

The light emitted from the light source 2 passes through the first member 61 and then passes through the third member 67. Specifically, the light from the light source 2 first passes through the antireflection coating 72, the substrate portion 62, the protective coating 75, and the antireflection coating 71 in this order. The light from the light source 2 then passes through the internal space S. When passing through the internal space S, the light from the light source 2 pumps atoms of the alkali metal 90 enclosed in the alkali vapor cell 6. The light having passed through the internal space S passes through the antireflection coating 73, the protective coating 77, the substrate portion 68, and the antireflection coating 74 in this order, and travels to the outside of the alkali vapor cell 6 (photodetector 8).

### Method for Producing Alkali Vapor Cell

Next, a method for producing the alkali vapor cell 6 is described. First, the first member 61, the second member 64, and the third member 67 are prepared. Then, the protective coating 75 is formed on the main surface 62a of the substrate portion 62 (first member 61). The protective coating 75 is formed by, for example, vapor deposition or sputtering. The protective coating 75 is formed on an inner region, of the main surface 62a, surrounded by a frame-shaped region (region where the bonding member 81 is to be formed) along the outer edge of the main surface 62a. In other words, the protective coating 75 is formed such that the outer edge of the protective coating 75 is located inside the outer edge of the main surface 62a. The protective coating 75 is formed of, for example, a material containing a material having low reactivity with respect to the alkali metal 90 (aluminum oxide, magnesium fluoride, or the like).

Then, the antireflection coating 71 is formed on the main surface 62a of the substrate portion 62 (first member 61). In this example, the antireflection coating 71 is formed on the main surface 62a via the protective coating 75. The antireflection coating 71 is directly formed on the protective coating 75. The antireflection coating 71 is formed by, for example, vapor deposition or sputtering. The antireflection coating 71 is formed on an inner region, of the main surface 62a, surrounded by a frame-shaped region (region where the bonding member 81 is to be formed) along the outer edge of the main surface 62a. In other words, the antireflection coating 71 is formed such that the outer edge of the antireflection coating 71 is located inside the outer edge of the main surface 62a.

The antireflection coating 71 is formed of, for example, an inorganic material such as aluminum oxide, silicon dioxide, magnesium fluoride, hafnium oxide, tantalum pentoxide, or titanium dioxide. In this example, the antireflection coating 71 is a multilayer coating, and is formed by stacking a plurality of layers 171. The antireflection coating 71 is formed by, for example, vapor deposition or sputtering.

Then, the antireflection coating 72 is formed on the main surface 62b of the substrate portion 62 (first member 61). The antireflection coating 72 is formed on the main surface 62b, to be exact, in an inner region surrounded by a frame-shaped region along the outer edge of the main surface 62b. In other words, the antireflection coating 72 is formed such that the outer edge of the antireflection coating 72 is located inside the outer edge of the main surface 62b. The antireflection coating 72 may be formed on the entirety of the main surface 62b. The antireflection coating 72 is formed of, for example, an inorganic material such as aluminum oxide, silicon dioxide, magnesium fluoride, hafnium oxide, tantalum pentoxide, or titanium dioxide. The antireflection coating 72 is formed by, for example, vapor deposition or sputtering.

Subsequently, the bonding member 81 is formed of silicon. The bonding member 81 is formed so as to surround the protective coating 75 and the antireflection coating 71 on the main surface 62a. In this example, the bonding member 81 is disposed in a rectangular frame shape along the outer edge of the main surface 62a. The bonding member 81 is disposed so as not to come into contact with the protective coating 75 and the antireflection coating 71. The bonding member 81 formed of silicon is bonded to the first member 61 formed of glass by anodic bonding. For example, heat and voltage are applied to the first member 61 and the bonding member 81, so that the first member 61 and the bonding member 81 are directly bonded to each other.

Subsequently, the protective coating 76 is formed on the inner surface 65c of the wall portion 65 (second member 64). The protective coating 76 is formed by, for example, vapor deposition or sputtering. In this example, the protective coating 76 is formed on the entirety of the inner surface 65c. The protective coating 76 is formed of, for example, a material containing a material having low reactivity with respect to the alkali metal 90 (aluminum oxide, magnesium fluoride, or the like).

Then, the first member 61 and the second member 64 are bonded to each other by anodic bonding. Specifically, first, the first member 61 and the second member 64 are disposed such that the bonding member 81 comes into contact with the end face 65a of the wall portion 65. In this state, the bonding member 81 formed of silicon and the wall portion 65 (second member 64) formed of glass are bonded to each other by anodic bonding. For example, heat and voltage are applied to the bonding member 81 and the wall portion 65, so that the bonding member 81 and the wall portion 65 are directly bonded to each other. As a result, the first member 61 and the second member 64 are bonded to each other via the bonding member 81.

Subsequently, the protective coating 77 is formed on the main surface 68a of the substrate portion 68 (third member 67). The protective coating 77 is formed by, for example, vapor deposition or sputtering. The protective coating 77 is formed on an inner region, of the main surface 68a, surrounded by a frame-shaped region (region where the bonding member 82 is to be formed) along the outer edge of the main surface 68a. In other words, the protective coating 77 is formed such that the outer edge of the protective coating 77 is located inside the outer edge of the main surface 68a. The protective coating 77 is formed of, for example, a material containing a material having low reactivity with respect to the alkali metal 90 (aluminum oxide, magnesium fluoride, or the like).

Then, the antireflection coating 73 is formed on the main surface 68a of the substrate portion 68 (third member 67). In this example, the antireflection coating 73 is formed on the main surface 68a via the protective coating 77. The antireflection coating 73 is directly formed on the protective coating 77. The antireflection coating 73 is formed by, for example, vapor deposition or sputtering. The antireflection coating 73 is formed on an inner region, of the main surface 68a, surrounded by a frame-shaped region (region where the bonding member 82 is to be formed) along the outer edge of the main surface 68a. In other words, the antireflection coating 73 is formed such that the outer edge of the antireflection coating 73 is located inside the outer edge of the main surface 68a.

The antireflection coating 73 is formed of, for example, an inorganic material such as aluminum oxide, silicon dioxide, magnesium fluoride, hafnium oxide, tantalum pentoxide, or titanium dioxide. In this example, the antireflection coating 73 is a multilayer coating, and is formed by stacking a plurality of layers 173. The antireflection coating 73 is formed by, for example, vapor deposition or sputtering.

Then, the antireflection coating 74 is formed on the main surface 68b of the substrate portion 68 (third member 67). The antireflection coating 74 is formed on an inner region, of the main surface 68b, surrounded by a frame-shaped region along the outer edge of the main surface 68b. In other words, the antireflection coating 74 is formed such that the outer edge of the antireflection coating 74 is located inside the outer edge of the main surface 68b. The antireflection coating 74 may be formed on the entirety of the main surface 68b. The antireflection coating 74 is formed of, for example, an inorganic material such as aluminum oxide, silicon dioxide, magnesium fluoride, hafnium oxide, tantalum pentoxide, or titanium dioxide. The antireflection coating 74 is formed by, for example, vapor deposition or sputtering.

Subsequently, the bonding member 82 is formed of silicon. The bonding member 82 is formed so as to surround the protective coating 77 and the antireflection coating 73 on the main surface 68a. In this example, the bonding member 82 is disposed in a rectangular frame shape along the outer edge of the main surface 68a. The bonding member 82 is disposed so as not to come into contact with the protective coating 77 and the antireflection coating 73. The bonding member 82 formed of silicon is bonded to the third member 67 formed of glass by anodic bonding. For example, heat and voltage are applied to the third member 67 and the bonding member 82, so that the third member 67 and the bonding member 82 are directly bonded to each other.

Subsequently, the alkali metal 90 is disposed on the inner surface 65c of the wall portion 65 (second member 64). In this example, the alkali metal 90 is disposed on the inner surface 65c via the protective coating 76. After the alkali metal 90 is disposed, the buffer gas 91 is introduced into the space (internal space S) surrounded by the wall portion 65.

Then, the third member 67 and the second member 64 are bonded to each other by anodic bonding. Specifically, first, the third member 67 and the second member 64 are disposed such that the bonding member 82 comes into contact with the end face 65b of the wall portion 65. In this state, the bonding member 82 formed of silicon and the second member 64 formed of glass are bonded to each other by anodic bonding. For example, heat and voltage are applied to the bonding member 82 and the second member 64, so that the bonding member 82 and the second member 64 are directly bonded to each other. As a result, the third member 67 and the second member 64 are bonded to each other via the bonding member 82. The first member 61 and the second member 64 are bonded to each other by anodic bonding via the bonding member 81, and the third member 67 and the second member 64 are bonded to each other by anodic bonding via the bonding member 82, so that the internal space S is hermetically sealed. Thus, the alkali vapor cell 6 is obtained.

### [Functions and Effects]

In the method for producing the alkali vapor cell 6 according to the present embodiment, the antireflection coating 71 is formed on the main surface 62a of the first member 61, and the antireflection coating 72 is formed on the main surface 62b of the first member 61. This reduces reflection of light that has transmitted through the alkali vapor cell 6 on the main surface 62a and the main surface 62b, so that measurement using the alkali vapor cell 6 can be accurately made. In the method for producing the alkali vapor cell 6, the first member 61 and the second member 64 are bonded to each other by anodic bonding. This reduces distortion of the first member 61 and the second member 64 due to heat and reduces destruction of the antireflection coating 71 and the antireflection coating 72, for example, as compared with a case where the first member 61 and the second member 64 are bonded to each other by heat sealing, so that measurement using the alkali vapor cell 6 can be accurately made. Further, in a case where the first member 61 and the second member 64 are bonded to each other using an adhesive or frit glass, there is a possibility that gas is released from the adhesive or the like. However, in the case of anodic bonding, such release of gas is reduced, so that measurement using the alkali vapor cell 6 can be accurately made. Thus, according to the method for producing the alkali vapor cell 6 of the present embodiment, it is possible to produce the alkali vapor cell 6 with which measurement can be accurately made. Further, another example of a method for bonding the first member 61 and the second member 64 is bonding by optical contact or metal diffusion. However, in the bonding method using optical contact or metal diffusion, it is necessary to polish the surface of a member to be bonded with high accuracy at the molecular level. In a state where the antireflection coating 71 is formed (coated), such polishing on the main surface 62a is difficult. In contrast, the anodic bonding does not involve such polishing. Therefore, according to the method for producing the alkali vapor cell 6 of the present embodiment, the first member 61 and the second member 64 can be bonded to each other by a simple method.

According to the method for producing the alkali vapor cell 6 of the present embodiment, the antireflection coating 71 can be formed by a simple method. For example, it may be difficult to form the antireflection coating 71 located inside the container 60 by vapor deposition or sputtering after bonding the first member 61 and the second member 64 in light of circumstances such as the shape of the container 60. Specifically, it is difficult to uniformly form the antireflection coating 71 and to control the film (coating) thickness. In this regard, the antireflection coating 71 can be formed by using atomic layer deposition (ALD) independent of the shape of the container 60 even after the first member 61 and the second member 64 are bonded to each other. However, the ALD process requires more time and cost compared to vapor deposition or sputtering. On the other hand, in the method for producing the alkali vapor cell 6 described above, after the antireflection coating 71 is formed, the first member 61 and the second member 64 are bonded to each other by anodic bonding. Accordingly, the antireflection coating 71 can be easily formed by vapor deposition or sputtering in a state where the first member 61 is not bonded to the second member 64. Therefore, according to the method for producing the alkali vapor cell 6 of the present embodiment, the antireflection coating 71 can be formed by a simple method (for example, vapor deposition or sputtering) without using the ALD process.

The method for producing the alkali vapor cell 6 according to the present embodiment includes a step of forming the bonding member 81 for bonding the first member 61 and the second member 64 with silicon. In the step of forming the bonding member 81, the bonding member 81 is formed so as to surround the antireflection coating 71 on the main surface 62a. In the step of bonding the first member 61 and the second member 64 to each other by anodic bonding, the first member 61 and the second member 64 are bonded to each other via the bonding member 81. As a result, by configuring the silicon member for anodic bonding different from the second member 64 (bonding member 81), the flexibility to select materials for the second member 64 is improved. For example, the second member 64 can be formed of glass that is relatively easily processed, and the first member 61 and the second member 64 can be bonded to each other by anodic bonding via the bonding member 81 (silicon member).

In the step of forming the antireflection coating 71, the antireflection coating 71 is formed by vapor deposition or sputtering. This enables the antireflection coating 71 to be formed by a simpler method.

In the step of forming the antireflection coating 72, the antireflection coating 72 is formed by vapor deposition or sputtering. This enables the antireflection coating 72 to be formed by a simpler method.

In the step of forming the antireflection coating 71, the antireflection coating 71 is formed of aluminum oxide, silicon dioxide, magnesium fluoride, hafnium oxide, tantalum pentoxide, or titanium dioxide. Thus, reflection of light on the main surface 62a can be reduced more reliably by the antireflection coating 71.

In the step of forming the antireflection coating 72, the antireflection coating 72 is formed of aluminum oxide, silicon dioxide, magnesium fluoride, hafnium oxide, tantalum pentoxide, or titanium dioxide. Thus, reflection of light on the main surface 62b can be reduced more reliably by the antireflection coating 72.

The second member 64 has the inner surface 65c that defines the internal space S of the container 60. The step of forming the protective coating 75 is a step of forming the protective coating 75 on the main surface 62a before the step of forming the antireflection coating 71. In the step of forming the protective coating 76, the protective coating 76 is formed on the inner surface 65c. As a result, a protective coating containing aluminum oxide or magnesium fluoride having relatively high resistance to the alkali metal 90 is formed on the main surface 62a and the inner surface 65c. This can reduce a chemical reaction between the alkali metal 90 and the main surface 62a (for example, corrosion of the main surface 62a) and a chemical reaction between the alkali metal 90 and the inner surface 65c (for example, corrosion of the inner surface 65c).

The alkali vapor cell 6 includes the first member 61 and the second member 64 that constitute at least a part of the container 60 for enclosing the alkali metal 90. The first member 61 has the main surface 62a that is an inner surface of the container 60 and the main surface 62b that is an outer surface of the container 60. The antireflection coating 71 is formed on the main surface 62a, and the antireflection coating 72 is formed on the main surface 62b. The first member 61 and the second member 64 are bonded to each other by anodic bonding.

According to the alkali vapor cell 6 of the present embodiment, the measurement can be accurately made for the same reason as described above.

### Second Embodiment

### Configuration of Alkali Vapor Cell

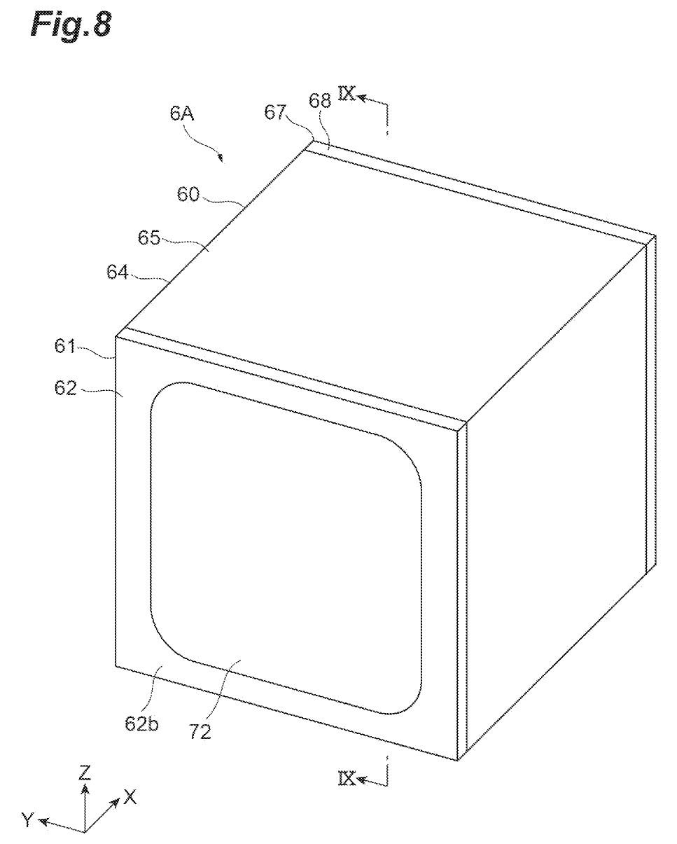

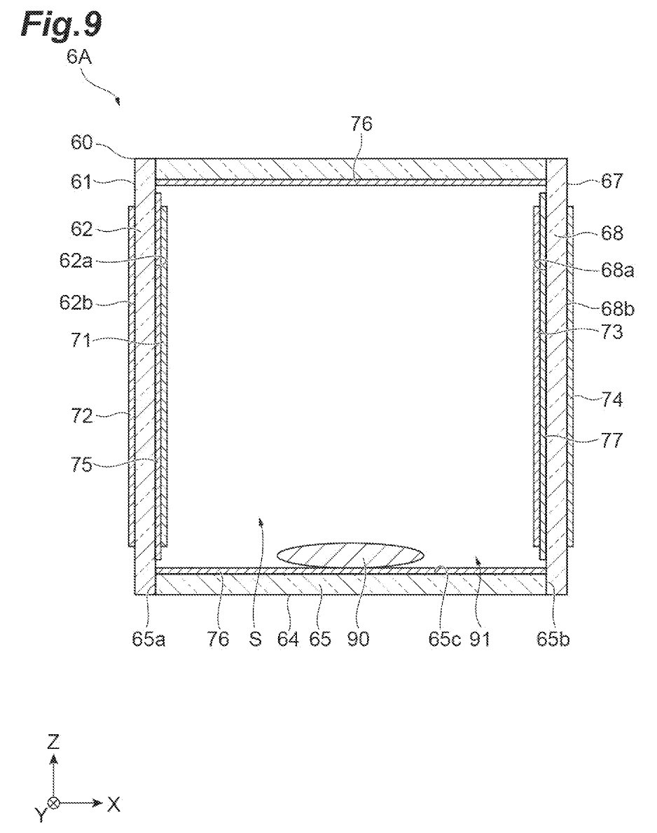

Next, an alkali vapor cell 6A according to the second embodiment will be described with reference to FIGS. 8 and 9. In the following description, differences between the alkali vapor cell 6A and the alkali vapor cell 6 will be mainly described, and description of common points will be omitted.

In the alkali vapor cell 6A, the wall portion 65 of the second member 64 is formed of silicon. In this example, the entire wall portion 65 is formed of silicon. The container 60 of the alkali vapor cell 6A does not include the bonding member 81 and the bonding member 82. The bonding member 81 is not formed between the first member 61 and the second member 64. The substrate portion 62 of the first member 61 and the wall portion 65 of the second member 64 are in direct contact with each other. In this example, the main surface 62a of the substrate portion 62 and the end face 65a of the wall portion 65 are in direct contact with each other. The first member 61 and the second member 64 are directly bonded to each other. The first member 61 and the second member 64 are bonded to each other by anodic bonding.

The bonding member 82 is not formed between the third member 67 and the second member 64. The substrate portion 68 of the third member 67 and the wall portion 65 of the second member 64 are in direct contact with each other. In this example, the main surface 68a of the substrate portion 68 and the end face 65b of the wall portion 65 are in direct contact with each other. The third member 67 and the second member 64 are directly bonded to each other. The third member 67 and the second member 64 are bonded to each other by anodic bonding.

### Method for Producing Alkali Vapor Cell

Next, a method for producing the alkali vapor cell 6A is described. First, the first member 61, the second member 64, and the third member 67 are prepared. Then, the protective coating 75 and the antireflection coating 71 are formed on the main surface 62a of the substrate portion 62 (first member 61), and the antireflection coating 72 is formed on the main surface 62b. The method for forming the protective coating 75 and the antireflection coatings 71 and 72 is similar to that of the first embodiment. Subsequently, the protective coating 76 is formed on the inner surface 65c of the wall portion 65 (second member 64). The method for forming the protective coating 76 is similar to that of the first embodiment.

Then, the first member 61 and the second member 64 are bonded to each other by anodic bonding. Specifically, first, the first member 61 and the second member 64 are disposed such that the main surface 62a of the substrate portion 62 comes into contact with the end face 65a of the wall portion 65. In this state, the substrate portion 62 (first member 61) formed of glass and the wall portion 65 (second member 64) formed of silicon are bonded to each other by anodic bonding. For example, heat and voltage are applied to the substrate portion 62 and the wall portion 65, so that the substrate portion 62 and the wall portion 65 are directly bonded to each other. As a result, the first member 61 and the second member 64 are directly bonded to each other.

Then, the protective coating 77 and the antireflection coating 73 are formed on the main surface 68a of the substrate portion 68 (third member 67), and the antireflection coating 74 is formed on the main surface 68b. The method for forming the protective coating 77 and the antireflection coatings 73 and 74 is similar to that of the first embodiment. Subsequently, the alkali metal 90 is disposed on the inner surface 65c of the wall portion 65 (second member 64) via the protective coating 76. After the alkali metal 90 is disposed, the buffer gas 91 is introduced into the space (internal space S) surrounded by the wall portion 65.

Then, the third member 67 and the second member 64 are bonded to each other by anodic bonding. Specifically, first, the third member 67 and the second member 64 are disposed such that the main surface 68a of the substrate portion 68 comes into contact with the end face 65b of the wall portion 65. In this state, the substrate portion 68 (third member 67) formed of glass and the wall portion 65 (second member 64) formed of silicon are bonded to each other by anodic bonding. For example, heat and voltage are applied to the substrate portion 68 and the wall portion 65, so that the substrate portion 68 and the wall portion 65 are directly bonded to each other. As a result, the third member 67 and the second member 64 are directly bonded to each other.

The first member 61 and the second member 64 are directly bonded to each other by anodic bonding, and the third member 67 and the second member 64 are directly bonded to each other by anodic bonding, so that the internal space S is hermetically sealed. Thus, the alkali vapor cell 6A is obtained.

According to the method for producing the alkali vapor cell 6A and the alkali vapor cell 6A of the present embodiment, the measurement can be accurately made for the same reason as that in the method for producing the alkali vapor cell 6 and the alkali vapor cell 6 described above.

In the method for producing the alkali vapor cell 6A, the second member 64 is formed of silicon, and in the step of bonding the first member 61 and the second member 64 to each other by anodic bonding, the first member 61 and the second member 64 are directly bonded to each other. As a result, the first member 61 and the second member 64 can be bonded to each other by anodic bonding without preparing a silicon member for anodic bonding as a configuration different from the second member 64. The second member 64 is formed of silicon having relatively high resistance to the alkali metal 90, which can reduce a chemical reaction between the alkali metal 90 and the second member 64 (for example, corrosion of the second member 64).

### Modification

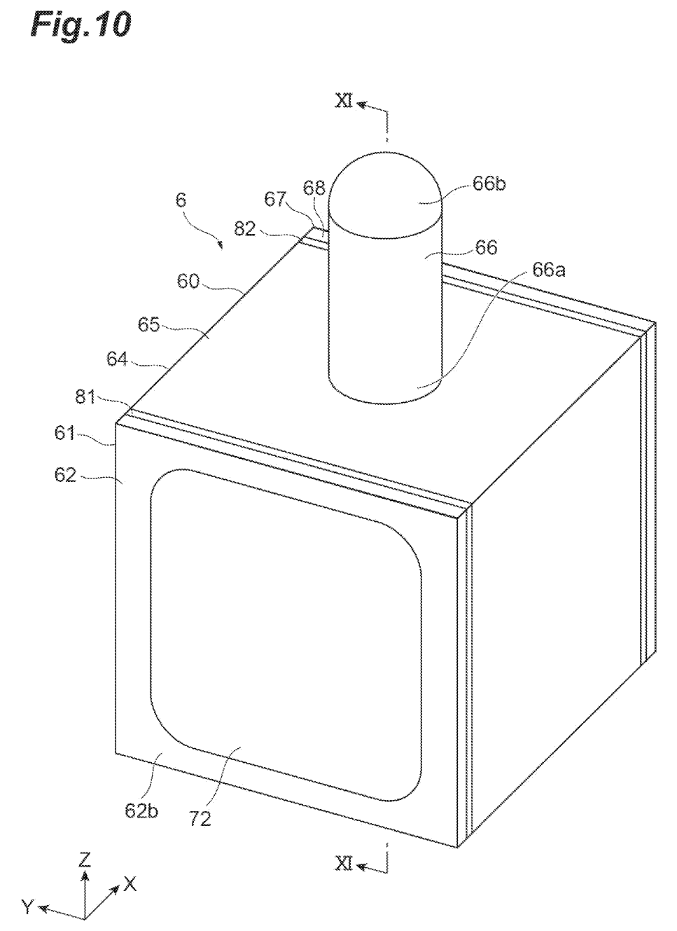

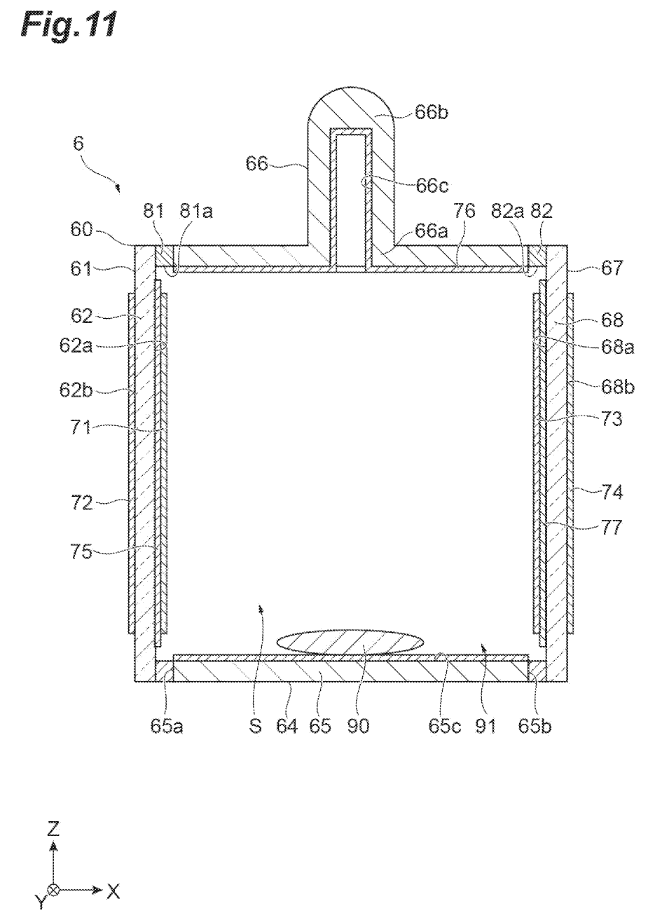

The present disclosure is not limited to the above embodiments. For example, as illustrated in FIGS. 10 and 11, in the first embodiment, the second member 64 may have the wall portion 65 extending so as to surround the space and a tube portion 66 formed on the wall portion 65. The configuration of the wall portion 65 is similar to the configuration described in the first embodiment. The tube portion 66 is a substantially cylindrical portion extending along the Z-axis direction. The tube portion 66 is formed of glass and formed integrally with the wall portion 65. The tube portion 66 may be formed separately from the wall portion 65. A first end 66a, which is one end of the tube portion 66, communicates with the space surrounded by the wall portion 65. The space inside the tube portion 66 and the space inside the wall portion 65 constitute the internal space S of the alkali vapor cell 6. A second end 66b, which is the other end of the tube portion 66, is sealed. In this example, the protective coating 76 is formed on the inner surface 65c of the wall portion 65 and the inner surface 66c of the tube portion 66. A configuration is possible in which the protective coating 76 is formed only on the inner surface 65c, and is not formed on the inner surface 66c.

In the production process of the alkali vapor cell 6 illustrated in FIGS. 10 and 11, the alkali metal 90 and the buffer gas 91 may be introduced into the internal space S through the tube portion 66. Specifically, in a state before the second end 66b of the tube portion 66 is sealed, the alkali metal 90 and the buffer gas 91 are introduced from the opening of the second end 66b. After the alkali metal 90 and so on are introduced, the second end 66b is sealed. The second end 66b may be sealed by using a tool or the like to press the tube portion 66 on the second end 66b side and press (cut) the tube portion 66 while crushing the tube portion 66, or a lid member for closing the opening of the second end 66b may be attached to the second end 66b. Thereby, the tube portion 66 is closed at the second end 66b, and the internal space S is sealed. Only the alkali metal 90 may be introduced into the internal space S without introducing the buffer gas 91 into the internal space S.

In the alkali vapor cell 6 according to the present modification, the second member 64 includes the wall portion 65 extending so as to surround the space and the tube portion 66 formed on the wall portion 65, and one end of the tube portion 66 communicates with the space (internal space S) surrounded by the wall portion 65. This allows, for example, the alkali metal 90 to be easily introduced into the alkali vapor cell 6 through the tube portion 66.

In the alkali vapor cell 6A according to the second embodiment, the second member 64 may further include the tube portion 66 described above. In this case, the tube portion 66 may be formed of silicon and be formed integrally with the wall portion 65. The tube portion 66 may be formed separately from the wall portion 65.

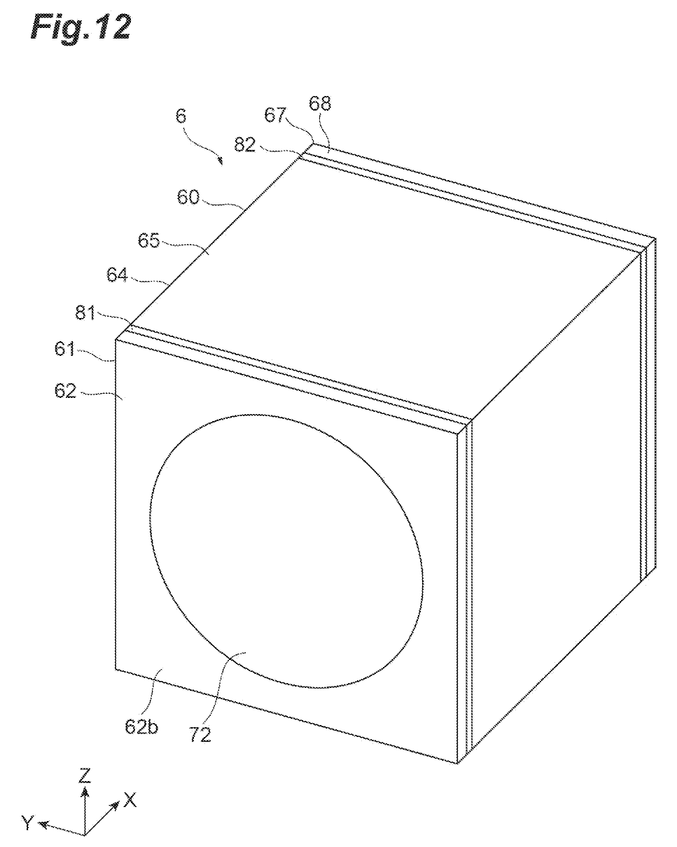

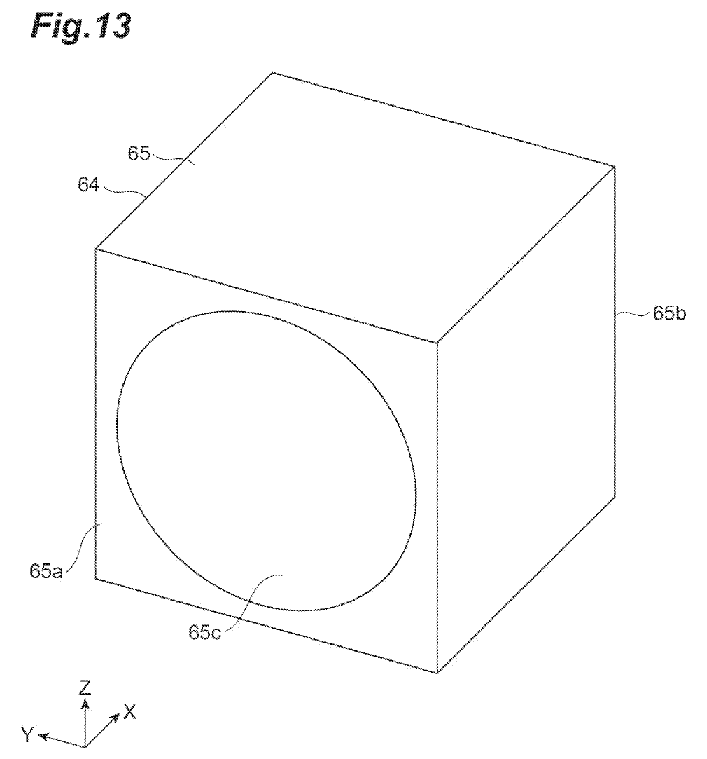

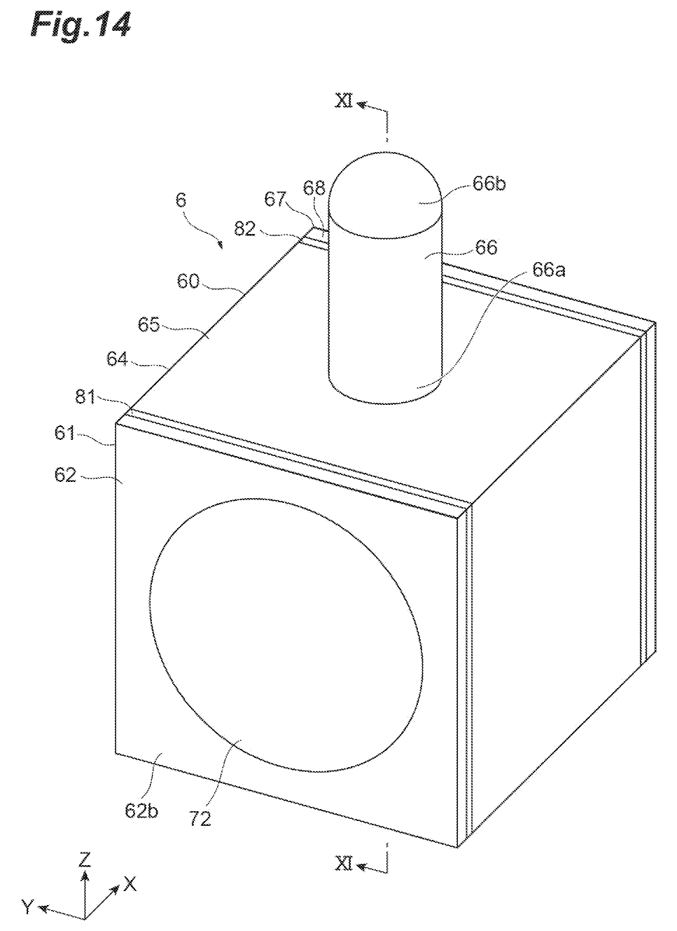

Another modification to the alkali vapor cell 6 will be described with reference to FIGS. 12 and 13. In the modification illustrated in FIGS. 12 and 13, each of the antireflection coatings 71, 72, 73, and 74 and the protective coatings 75 and 77 is formed in a circular shape when viewed from the X-axis direction. When viewed from the X-axis direction, the inner edge (inner surface 65c) of the wall portion 65 has a circular shape. When viewed from the X-axis direction, the outer edges of the antireflection coatings 71, 72, 73, and 74 and the protective coatings 75 and 77 extend along the inner edge of the wall portion 65. When viewed from the X-axis direction, the centers of the antireflection coatings 71, 72, 73, and 74 and the protective coatings 75 and 77 are aligned with the center of the inner edge of the wall portion 65. When viewed from the X-axis direction, the inner edges (inner surfaces 81a and 82a) of the bonding members 81 and 82 each have a circular shape along the inner edge of the wall portion 65. When viewed from the X-axis direction, the outer edges of the bonding members 81 and 82 each have a rectangular shape along the outer edge of the wall portion 65. In the modification illustrated in FIGS. 12 and 13, the second member 64 may further include the tube portion 66 described above (see FIG. 14).

The configuration according to the modification illustrated in FIGS. 12 and 13 may be applied to the alkali vapor cell 6A (FIGS. 8 and 9) according to the second embodiment. Specifically, in the alkali vapor cell 6A, each of the antireflection coatings 71, 72, 73, and 74 and the protective coatings 75 and 77 may be formed in a circular shape when viewed from the X-axis direction. In the alkali vapor cell 6A, the inner edge (inner surface 65c) of the wall portion 65 may have a circular shape when viewed from the X-axis direction. In the configuration, the second member 64 may further include the tube portion 66 described above.

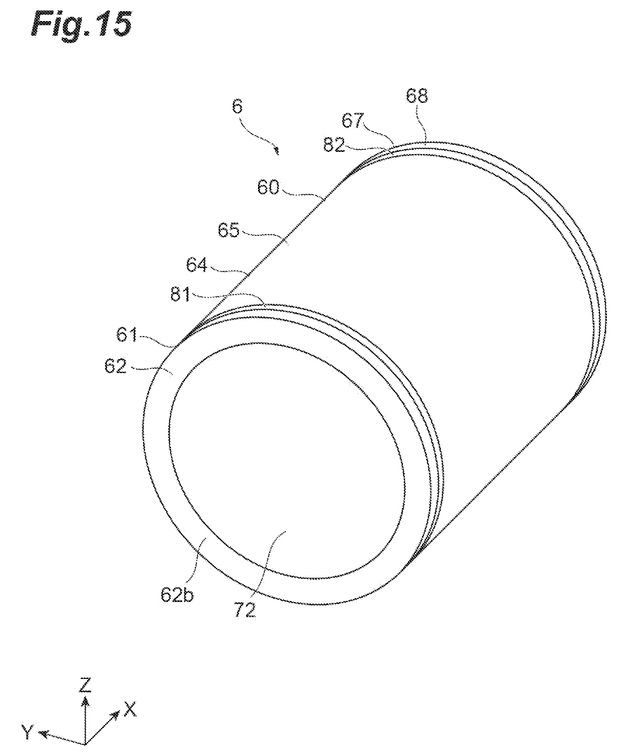

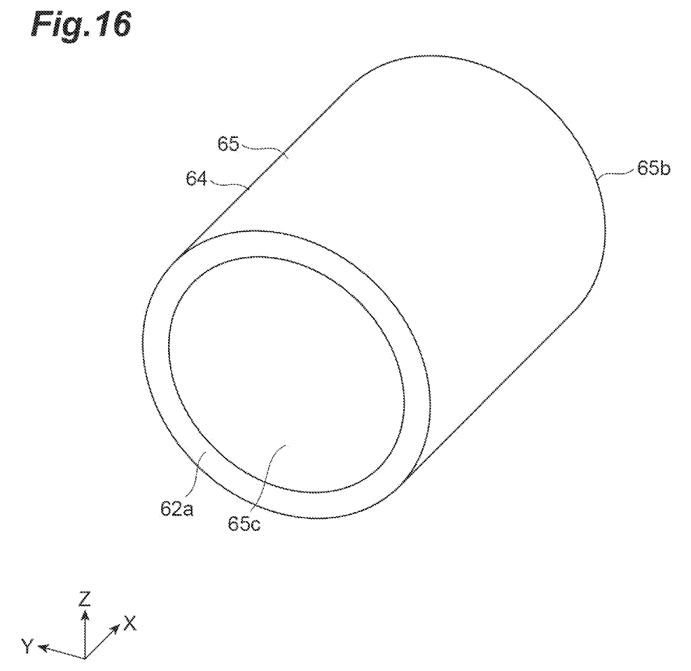

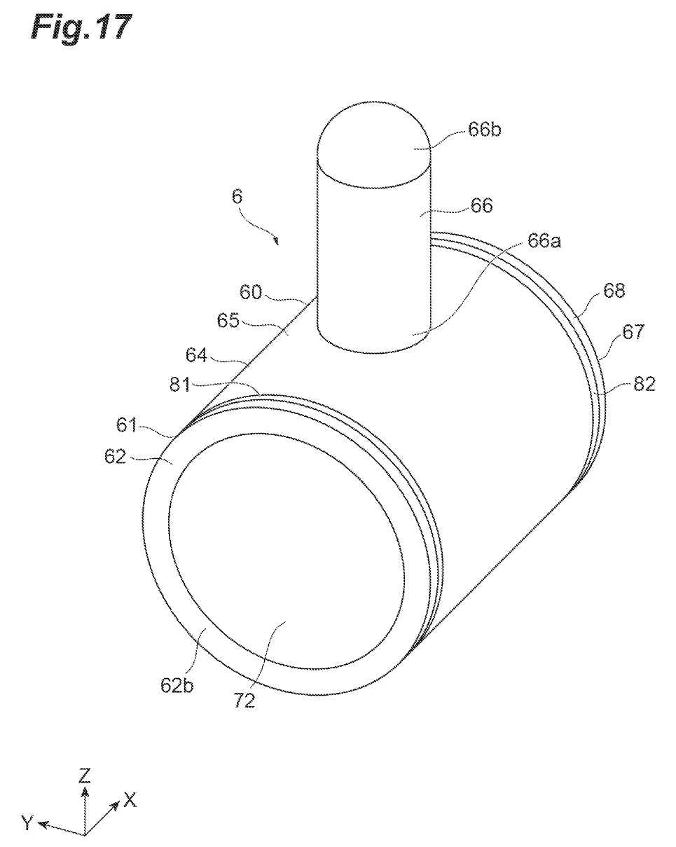

Another modification to the alkali vapor cell 6 will be described with reference to FIGS. 15 and 16. In the modification illustrated in FIGS. 15 and 16, each of the substrate portions 62 and 68 is formed in a circular plate shape having a thickness along the X-axis direction. When viewed from the X-axis direction, the diameter of each of the substrate portions 62 and 68 is, for example, about several millimeters. Each of the main surfaces 62a, 62b, 68a, and 68b has a circular shape when viewed from the X-axis direction. Each of the antireflection coatings 71, 72, 73, and 74 and the protective coatings 75 and 77 is formed in a circular shape when viewed from the X-axis direction. When viewed from the X-axis direction, each of the inner edge (inner surface 65c) and the outer edge of the wall portion 65 has a circular shape. When viewed from the X-axis direction, the outer edges of the antireflection coatings 71, 72, 73, and 74 and the protective coatings 75 and 77 extend along the inner edge of the wall portion 65. When viewed from the X-axis direction, the centers of the antireflection coatings 71, 72, 73, and 74 and the protective coatings 75 and 77 are aligned with the center of the inner edge of the wall portion 65. When viewed from the X-axis direction, each of the bonding members 81 and 82 extends in a circular annular shape. That is, when viewed from the X-axis direction, the inner edges (inner surfaces 81a and 82a) of the bonding members 81 and 82 each have a circular shape along the inner edge of the wall portion 65. When viewed from the X-axis direction, the outer edges of the bonding members 81 and 82 each have a circular shape along the outer edge of the wall portion 65. In the modification illustrated in FIGS. 15 and 16, the second member 64 may further include the tube portion 66 described above (see FIG. 17).

The configuration according to the modification illustrated in FIGS. 15 and 16 may be applied to the alkali vapor cell 6A (FIGS. 8 and 9) according to the second embodiment. Specifically, in the alkali vapor cell 6A, each of the substrate portions 62 and 68 may be formed in a circular plate shape having a thickness along the X-axis direction. In the alkali vapor cell 6A, each of the antireflection coatings 71, 72, 73, and 74 may be formed in a circular shape when viewed from the X-axis direction. In the alkali vapor cell 6A, each of the inner edge (inner surface 65c) and the outer edge of the wall portion 65 may have a circular shape when viewed from the X-axis direction. In the configuration, the second member 64 may further include the tube portion 66 described above.

After the bonding member 81 is formed on the main surface 62a of the substrate portion 62 (first member 61), the antireflection coating 71 and the protective coating 75 may be formed on the main surface 62a. In this case, the antireflection coating 71 and the protective coating 75 may be formed by vapor deposition, sputtering, or the like in a state where the bonding member 81 is covered with a mask or the like. After the bonding member 82 is formed on the main surface 68a of the substrate portion 68 (third member 67), the antireflection coating 73 and the protective coating 77 may be formed on the main surface 68a. In this case, the antireflection coating 73 and the protective coating 77 may be formed by vapor deposition, sputtering, or the like in a state where the formed bonding member 82 is covered with a mask or the like.

In the production process of the alkali vapor cells 6 and 6A, the bonding member 81 may be formed (disposed) on the second member 64. For example, the bonding member 81 may be formed on the end face 65a of the wall portion 65. In this case, after the bonding member 81 and the second member 64 are bonded to each other, the bonding member 81 and the first member 61 may be bonded to each other. Similarly, in the production process of the alkali vapor cells 6 and 6A, the bonding member 82 may be formed (disposed) on the second member 64. For example, the bonding member 82 may be formed on the end face 65b of the wall portion 65. In this case, after the bonding member 82 and the second member 64 are bonded to each other, the bonding member 82 and the third member 67 may be bonded to each other.

The bonding members 81 and 82 may be discontinuous instead of being continuous. Each of the bonding member 81 and the bonding member 82 may not be formed in a frame shape.

The antireflection coatings 71, 72, 73, and 74 may be formed by a method other than vapor deposition or sputtering. The material of the antireflection coatings 71, 72, 73, and 74 may be a material other than aluminum oxide, silicon dioxide, magnesium fluoride, hafnium oxide, tantalum pentoxide, and titanium dioxide. The protective coatings 75, 76, and 77 may be formed by a method other than vapor deposition or sputtering. The material of the protective coatings 75, 76, and 77 may be a material other than aluminum oxide and magnesium fluoride without containing aluminum oxide or magnesium fluoride.

The light emitted from the light source 2 may pass through the third member 67 and then pass through the first member 61. In this case, the light from the light source 2 first passes through the antireflection coating 74, the substrate portion 68, the protective coating 77, and the antireflection coating 73 in this order. The light from the light source 2 then passes through the internal space S. When passing through the internal space S, the light from the light source 2 pumps atoms of the alkali metal 90 enclosed in the alkali vapor cell 6. The light having passed through the internal space S passes through the antireflection coating 71, the protective coating 75, the substrate portion 62, and the antireflection coating 72 in this order, and travels to the outside of the alkali vapor cell 6 (photodetector 8).

Another configuration is possible in which the alkali vapor cell 6 does not have the protective coatings 75, 76, and 77. In this case, the antireflection coating 71 may be formed directly on the main surface 62a without the protective coating 75. The antireflection coating 73 may be formed directly on the main surface 68a without the protective coating 77.

What is claimed is:

1. A method for producing an alkali vapor cell, comprising:
a step of preparing a first member and a second member constituting at least a part of a container for enclosing an alkali metal;
a step of forming a first antireflection film on a first surface of the first member;
a step of forming a second antireflection film on a second surface of the first member, the second surface being opposite to the first surface; and
a step of bonding the first member and the second member to each other by anodic bonding.

2. The method for producing an alkali vapor cell according to claim 1, further comprising:
a step of forming a bonding member for bonding the first member and the second member with silicon, wherein
in the step of forming the bonding member, the bonding member is formed so as to surround the first antireflection film on the first surface, and
in the step of bonding, the first member and the second member are bonded to each other via the bonding member.

3. The method for producing an alkali vapor cell according to claim 1, wherein
the second member is formed of silicon, and
in the step of bonding, the first member and the second member are directly bonded to each other.

4. The method for producing an alkali vapor cell according to claim 1, wherein
the second member includes a wall portion extending so as to surround a space and a tube portion formed on the wall portion, and
one end of the tube portion communicates with the space.

5. The method for producing an alkali vapor cell according to claim 1, wherein
in the step of forming the first antireflection film, the first antireflection film is formed by vapor deposition or sputtering.

6. The method for producing an alkali vapor cell according to claim 1, wherein
in the step of forming the second antireflection film, the second antireflection film is formed by vapor deposition or sputtering.

7. The method for producing an alkali vapor cell according to claim 1, wherein
in the step of forming the first antireflection film, the first antireflection film is formed of aluminum oxide, silicon dioxide, magnesium fluoride, hafnium oxide, tantalum pentoxide, or titanium dioxide.

8. The method for producing an alkali vapor cell according to claim 1, wherein
in the step of forming the second antireflection film, the second antireflection film is formed of aluminum oxide, silicon dioxide, magnesium fluoride, hafnium oxide, tantalum pentoxide, or titanium dioxide.

9. The method for producing an alkali vapor cell according to claim 1, further comprising:
a step of forming, on the first member, a first protective film containing aluminum oxide or magnesium fluoride; and
a step of forming, on the second member, a second protective film containing aluminum oxide or magnesium fluoride, wherein
the second member includes a third surface defining an internal space of the container,
the step of forming the first protective film is a step of forming the first protective film on the first surface before the step of forming the first antireflection film, and
in the step of forming the second protective film, the second protective film is formed on the third surface.

10. An alkali vapor cell comprising:
a first member and a second member constituting at least a part of a container for enclosing an alkali metal; and
a first antireflection film and a second antireflection film formed on the first member, wherein
the first member includes a first surface and a second surface, the first surface being an inner surface of the container, the second surface being located on a side opposite to the first surface and being an outer surface of the container,
the first antireflection film is formed on the first surface,
the second antireflection film is formed on the second surface, and
the first member and the second member are bonded to each other by anodic bonding.

11. The alkali vapor cell according to claim 10, further comprising:
a bonding member formed on the first surface so as to surround the first antireflection film, wherein
the bonding member is formed of silicon, and
the first member and the second member are bonded to each other via the bonding member.

12. The alkali vapor cell according to claim 10, wherein
the second member is formed of silicon, and
the first member and the second member are directly bonded to each other.

13. The alkali vapor cell according to claim 10, wherein
the second member includes a wall portion extending so as to surround a space and a tube portion formed on the wall portion, and
one end of the tube portion communicates with the space.

14. The alkali vapor cell according to claim 10, wherein
the first antireflection film is formed of aluminum oxide, silicon dioxide, magnesium fluoride, hafnium oxide, tantalum pentoxide, or titanium dioxide.

15. The alkali vapor cell according to claim 10, wherein
the second antireflection film is formed of aluminum oxide, silicon dioxide, magnesium fluoride, hafnium oxide, tantalum pentoxide, or titanium dioxide.

16. The alkali vapor cell according to claim 10, further comprising:
a first protective film formed on the first member and containing aluminum oxide or magnesium fluoride; and
a second protective film formed on the second member and containing aluminum oxide or magnesium fluoride, wherein
the second member includes a third surface defining an internal space of the container,
the first protective film is formed on the first surface, and
the second protective film is formed on the third surface.
